(19) United States
(12) Patent Application Publication
(10) Pub. No.: US 2007/0037101 A1
(43) Pub. Date: Feb. 15, 2007

(54) Manufacture method for micro structure

(75) Inventor: Hiroshi Morioka, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/269,579

(22) Filed: Nov. 9, 2005

(30) Foreign Application Priority Data
Aug. 15, 2005 (JP) 2005-235435

(51) Int. Cl. G03F 7/26

(52) U.S. Cl. 430/313; 430/311

(57) ABSTRACT

A micro structure manufacture method includes the steps of: (a) preparing an etching object having an etching target film, provided with a lower hard mask layer and an upper hard mask layer stacked on the etching target film; (b) forming a resist pattern above the etching object; (c) etching the upper hard mask film by using the resist pattern as an etching mask to form an upper hard mask; (d) after the step (c), removing the resist pattern; (e) after the step (d), thinning the upper hard mask by etching; (f) etching the lower hard mask film by using the thinned upper hard mask as an etching mask to form a lower hard mask; and (g) etching the etching target film by using the upper hard mask and the lower hard mask as an etching mask, wherein the upper hard mask film is capable of being more easily etched, using the resist pattern as a mask, than the lower hard mask film. The micro structure manufacture method can etch a fine pattern with good yield.

### CROSS REFERENCE TO RELATED APPLICATION

This application is based on and claims priority of Japanese Patent Application No. 2005-235435 filed on Aug. 15, 2005, the entire contents of which are incorporated herein by reference.

### BACKGROUND OF THE INVENTION

A) Field of the Invention

The present invention relates to a manufacture method for a micro structure, and more particularly to a manufacture method for a micro structure having a pattern narrower than the minimum size of a resist pattern exposed and developed.

B) Description of the Related Art

The current processing of semiconductor devices generally uses techniques of etching various films such as silicon films, silicon oxide films, and silicon nitride films by reactive ion etching (RIE) using a resist pattern formed by lithography. A light source of photolithography has changed from KrF excimer laser (wavelength 248 nm) to ArF excimer laser (wavelength 193 nm) to form finer resist patterns. Resist material changes with the wavelength of an exposure light source.

Each photolithography technique has its own attainable minimum size. Trimming is performed to realize a pattern width narrower than the minimum size. For example, fine line patterns having a width of 100 nm or narrower are necessary for forming a gate electrode of a MOS transistor and a bit line of DRAM. These fine resist patterns having a width of 100 nm or narrower are formed by narrowing (trimming) a wider initial resist pattern by isotropic etching.

Japanese Patent Laid-open Publication No. 2004-31944 demonstrates the technique of forming a hard mask film of silicon oxide, silicon nitride, silicon oxynitride or the like on a gate electrode polysilicon film, forming a resist pattern for 248 nm on the hard mask film, trimming the resist pattern by isotropic etching, etching the hard mask film, removing the left resist pattern by ashing, and etching the polysilicon film by using the hard mask film as a mask. This Publication points out the problems that at the exposure wavelength of 193 nm, resist is not so stable, edge roughness having coarse pattern lines increases, a resist film thickness after trimming is insufficient, or if a height is made sufficient, the resist pattern falls.

An embodiment of Japanese Patent Laid-open Publication No. 2004-31944 proposes a method of etching a film. According to this method, resist material mainly used is photosensitive to a short wavelength of 193 nm but is not stable. After a resist pattern is formed on a hard mask film, the resist pattern is transferred to the hard mask film by etching, both the resist pattern and hard mask film are trimmed at the same time to form a pattern having a desired size, thereafter an etching target film is etched. For example, the hard mask film has a three-layer structure of a silicon-rich silicon nitride film, a silicon oxynitride film and a silicon oxide film. Trimming is not performed before the hard mask is etched.

Japanese Patent Disclosed Publication No. 2004-530922 proposes a method of forming a resist pattern through exposure and development, reforming a surface layer of the resist pattern with an electron beam to set different etch rates between vertical and horizontal directions, and trimming the resist pattern by etching having preference to the horizontal direction to extinguish the reformed surface layer at the same time when trimming is completed.

Japanese Patent Laid-open Publication No. 2005-45214 proposes a method of realizing a uniform pattern width in a process of forming a resist pattern through exposure and development and trimming the resist pattern having a desired width. According to this method, if widths of exposed and developed resist patterns are different because of sparse/dense pattern distributions, differences between pattern widths are compensated by the trimming process to realize a uniform pattern width.

### SUMMARY OF THE INVENTION

An object of this invention is to provide a micro structure manufacture method capable of etching a fine pattern with good yield.

Another object of this invention is to provide a fine pattern manufacture method capable of etching a narrow pattern while using a resist pattern is limited in the range where deformation of the resist pattern can be easily prevented.

According to one aspect of the present invention, there is provided a micro structure manufacture method comprising the steps of: (a) preparing an etching object having an etching target film, provided with a lower hard mask layer and an upper hard mask layer stacked on the etching target film; (b) forming a resist pattern above said etching object; (c) etching said upper hard mask film by using said resist pattern as an etching mask to form an upper hard mask;

(d) after said step (c), removing said resist pattern; (e) after said step (d), thinning said upper hard mask by etching; (f) etching said lower hard mask film by using said thinned upper hard mask as an etching mask to form a lower hard mask; and (g) etching said etching target film by using said upper hard mask and said lower hard mask as an etching mask, wherein said upper hard mask film is capable of being more easily etched, using said resist pattern as a mask, than said lower hard mask film.

The resist pattern is used as a mask for etching the upper hard mask. The upper hard mask can be patterned more easily than the lower hard mask by using the resist pattern as a mask. The resist pattern can therefore be transferred to the upper hard mask with good controllability. At the time when the upper hard mask film is trimmed to form an object fine pattern, the resist pattern which might cause pattern defects is already removed so that generation of pattern defects can be prevented. A fine pattern is transferred from the upper hard mask to the lower hard mask, and the etching target film is etched by using the upper and lower hard masks as an etching mask so that the fine pattern can be manufactured with good yield.

### BRIEF DESCRIPTION OF THE DRAWINGS

FIGS. 1A to 1H are cross sectional views of a semiconductor substrate illustrating main processes of a micro structure manufacture method according to a first embodiment.

FIG. 2 is a table summarizing the conditions of processes of the first embodiment.

FIGS. 3A and 3B are SEM photographs showing samples of gate electrodes of polysilicon formed according to prior art.

FIG. 4 is a SEM photograph showing samples of gate electrodes of polysilicon formed according to the first embodiment.

FIGS. 5A to 5F are cross sectional views of a semiconductor substrate illustrating a manufacture method for a CMOS semiconductor device applying the first embodiment method.

FIGS. 6A to 6D are cross sectional views of a semiconductor substrate illustrating main processes of a micro structure manufacture method according to a second embodiment.

FIGS. 7A to 7D are cross sectional views of a semiconductor substrate illustrating main processes of a micro structure manufacture method according to a third embodiment.

### DESCRIPTION OF THE PREFERRED EMBODIMENTS

First, preliminary studies made by the present inventor will be described.

If the processing size becomes small, e.g., 100 nm or narrower, an aspect ratio (height/width) of a resist pattern becomes very large in order to obtain a resist film thickness necessary for RIE of an etching target film, and there occurs a phenomenon that a resist pattern is deformed by thermal stress or the like due to ion collision during dry etching.

Even if an aspect ratio is small, the shape of a fine resist pattern changes because of fast erosion at a sharp edge, and defect patterns such as broken lines are likely to be formed.

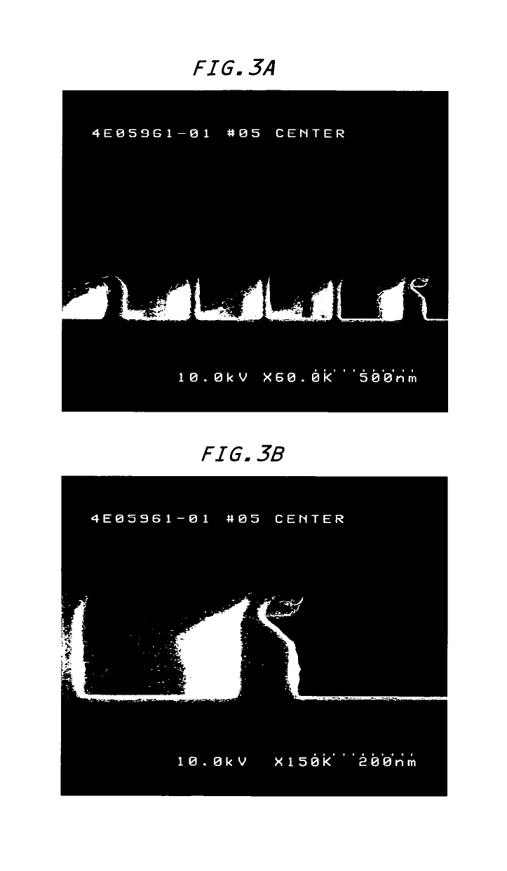

FIGS. 3A and 3B show defective shapes of resist patterns when a polysilicon gate electrode layer is subjected to RIE by using resist patterns as a mask. A pattern at the rightmost in FIG. 3A is abnormal. FIG. 3B is an enlarged view of the rightmost pattern. The resist pattern, having a width of 50 nm or narrower if the resist is not damaged, is bent and the pattern width as viewed in plan increases greatly, because of thermal stress due to RIE ion collision and damages due to halogen radicals or the like having high reactivity. With this shape change, the pattern width of the lower polysilicon film broadens greatly. A fine resist pattern is likely to be deformed by the influence of RIE.

It can be considered that a resist pattern can be lowered by transferring a resist pattern to a hard mask film and etching an etching target film by using the hard mask film as an etching mask. However, this approach does not solve the problem that a fine resist pattern is likely to be deformed. In order to etch a silicon oxide film, a silicon nitride film, a silicon oxynitride film, a lamination thereof and the like which are often used conventionally as a hard mask, it is necessary to use ions having a higher energy than that for etching polysilicon. The influence of this high energy ions upon a fine resist pattern cannot be neglected. It is desired to form a hard mask capable of mitigating the influence upon a resist pattern.

First, an upper hard mask is processed by using as a mask a resist pattern having a width capable of suppressing falling and breaking of the resist pattern. It is desired to select material of the upper hard mask which material is easy to be patterned by using the resist pattern and has good formability. After the resist pattern is removed, the upper hard mask is trimmed. The resist pattern is removed before the upper hard mask defines a target fine pattern. Since the resist causing defective patterns such as falling and braking does not exist when an upper hard mask pattern defining the target fine pattern is formed, defective patterns can be avoided.

If silicon such as polysilicon and amorphous silicon is used as the material of the upper hard mask film, the upper hard mask film can be dry-etched by using gas which contains halogen element such as HBr capable of suppressing a resist film reduction and by using a resist pattern as a mask. In preliminary tests, fine patterns having a width of about 50 nm were able to be processed without any defect. Narrowing the width of a resist pattern by trimming it before an upper hard mask is etched is not essential in the present invention. However, this trimming may be performed because the amount of subsequent trimming of the upper hard mask can be reduced. Both the trimming processes may be combined properly.

Material capable of being etched with good controllability without giving large damages to a resist pattern does not necessarily have the good property as a hard mask. If an etching target film is made of silicon, a hard mask made of only silicon cannot be used. A hard mask having a lamination structure is therefore used.

The upper hard mask layer is trimmed to transfer it to a lower hard mask layer having a high resistance against RIE. An etching target film is processed by using the upper and lower hard mask films as an etching mask.

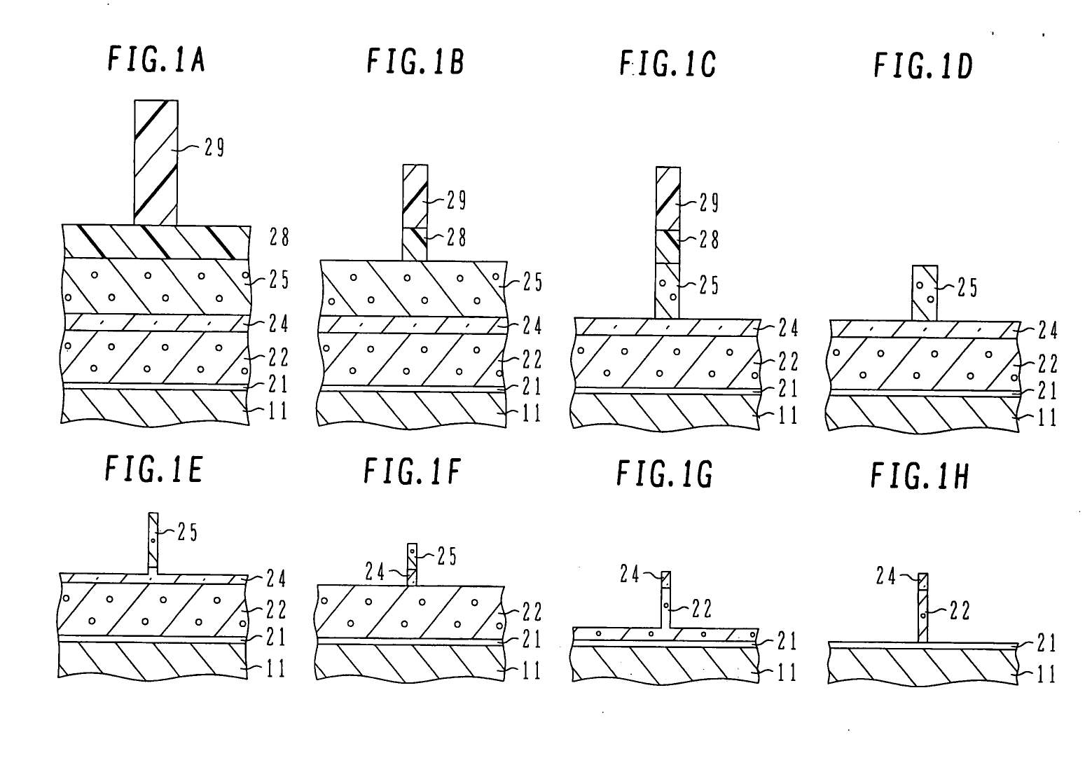

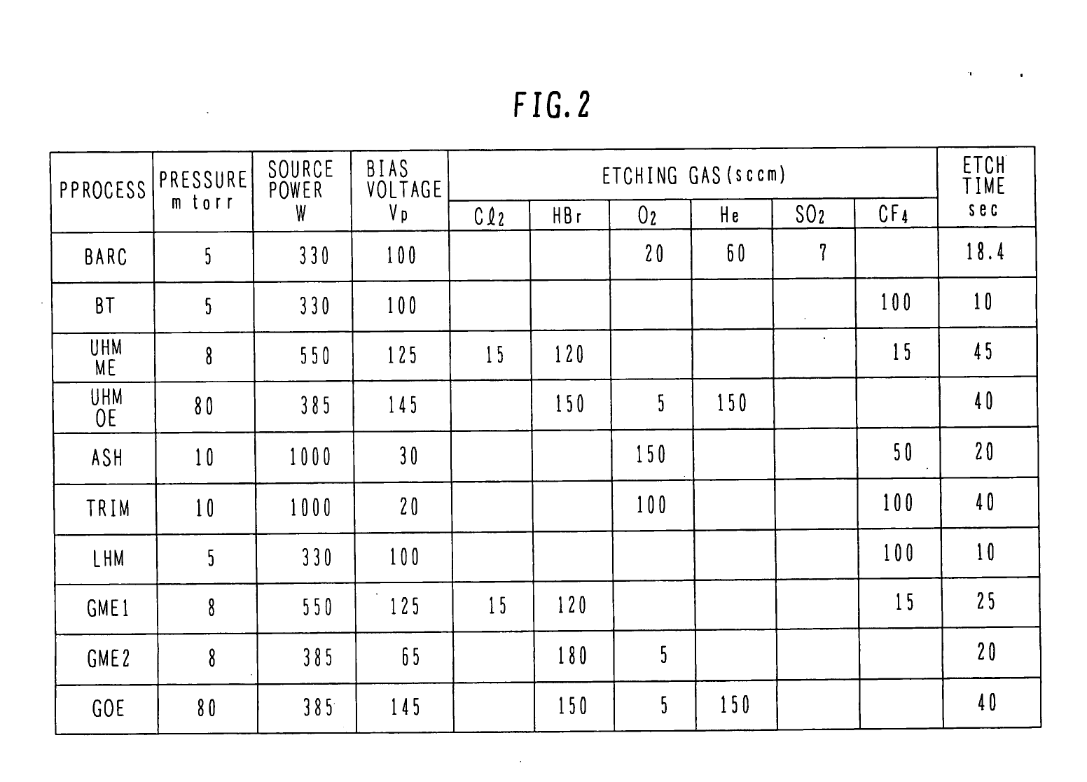

With reference to FIGS. 1A to 1H, the first embodiment will be described. FIGS. 1A to 1H are cross sectional views of a semiconductor substrate illustrating main processes of a micro structure manufacture method. A series of etching/trimming processes is executed by using, for example, an inductively coupled plasma (ICP) etcher. A table in FIG. 2 shows a summary of process conditions.

As shown in FIG. 1A, the surface of a silicon substrate 11 is thermally oxidized and nitrogen or the like is introduced to form a silicon oxynitride film 21 having a thickness of about 1 nm, the silicon oxynitride film constituting a gate insulating film. A polysilicon film 22 constituting gate electrodes is deposited on the gate insulating film 21 to a thickness of 105 nm by thermal CVD. The polysilicon film 22 is an etching target film. A silicon oxide film 24 as a lower hard mask film is deposited on the polysilicon film 22 to a thickness of 30 nm by thermal CVD, and a polysilicon film 25 as an upper hard mask film is deposited on the silicon oxide film 24 to a thickness of 105 nm by thermal CVD. A bottom antireflection film (BARC) 28 for ArF lithography having a thickness of, e.g., 76 nm and an ArF resist film 29 having a thickness of, e.g., about 200 to 250 nm are formed on and above the upper hard mask film 25. The BARC film 28 is an organic film having a composition similar to that of the resist film 29 although it has no photosensitivity.

The resist film is exposed and developed with an ArF excimer laser beam to form a resist pattern 29 having a width of 150 nm or narrower, e.g., about 80 nm to 100 nm. The width 80 nm is considerably wider than a final target pattern width. The BARC film 28 is etched by using the resist pattern 29 as a mask. For example, the underlying silicon surface was exposed by etching for 18.4 seconds by using mixture gas of He/O₂/SO₂ (flow rate: 60/20/7 sccm) or the like under the conditions of an in-chamber pressure of 5 mtorr (665 mPa), an RF source power of 330 W and an RF bias peak voltage of 100 V.

As shown in FIG. 1B, over-etching is performed to trim a lamination of the resist pattern 29 and BARC pattern 28. While the BARC film 28 is etched, the lamination of the resist pattern 29 and BARC pattern 28 is trimmed to a width of, e.g., about 40 to 50 nm. For example, the over-etching of 30% is performed after detecting an etching end point when the underlying polysilicon film is exposed. The lamination of the trimmed resist pattern 29 and BARC pattern 28 is used as a mask pattern for etching the polysilicon film 25.

As a breakthrough (BT) for exposing a clean silicon surface by removing an oxide film possible formed on the silicon surface, a surface cleaning process is performed for 10 seconds by changing etching gas to CF₄ (flow rate: 100 sccm).

As shown in FIG. 1C, the polysilicon film 25 as the upper hard mask (UHM) is etched by RIE to transfer the resist pattern to the upper hard mask film 25, by using as a mask the lamination of the resist pattern 29 and BARC pattern 28 and using etching gas which contains HBr as a main composition. The etching gas which contains HBr as a main composition provides a small resist pattern film reduction. It is therefore possible to transfer the resist pattern to the upper hard mask at a high precision. The side walls of the upper hard mask can be made vertical.

For example, as a main etching (ME), RIE is performed for 45 seconds by using mixture gas of Cl₂/HBr/CF₄ (flow rate: 15/120/15 sccm) under the conditions of an in-chamber pressure of 8 mtorr (1064 mPa), an RF source power of 550 W and an RF bias peak voltage of 125 V. As an over-etching (OE), RIE is performed for 40 seconds by using mixture gas of HBr/O₂/He (flow rate: 150/5/150 sccm) under the conditions of an in-chamber pressure of 80 mtorr (10640 mPa), an RF source power of 385 W and an RF bias peak voltage of 145 V.

As shown in FIG. 1D, while the vacuum state is maintained, the lamination of the resist pattern 29 and BARC pattern 28 is removed by ashing (ASH) by changing etching gas to O₂/CF₄ or the like. By adding CF₄ gas to O₂ gas, it is possible to remove the lamination of the resist pattern 29 and BARC pattern 28 and residues derived from Si.

For example, ashing is performed for 20 seconds by using mixture gas of O₂/CF₄ (flow rate: 150/50 sccm) under the conditions of a pressure of 10 mtorr (1330 mPa) an RF source power of 1000 W and an RF bias peak voltage of 30V.

As shown in FIG. 1E, the upper hard mask pattern 25 of polysilicon is trimmed (TRIM) by using etching gas of O₂/CF₄ or the like. The width of the trimmed hard mask is 100 nm or narrower, e.g., 15 to 20 nm. This width is a target pattern width.

For example, trimming is performed for 40 seconds by using etching gas of O₂/CF₄ (flow rate: 100/100 sccm) under the conditions of an in-chamber pressure of 10 mtorr (1330 mPa), an RF power of 100 W and an RF bias peak voltage of 20 V. A ratio of CF₄ to O₂ is raised to etch silicon at a proper etching (trimming) rate.

As shown in FIG. 1F, the silicon oxide film 24 as the lower hard mask (LHM) is etched by RIE by using etching gas of CF₄ or the like and using the upper hard mask pattern as a mask. The hard mask of silicon oxide is widely used and has high process stability and reliability.

For example, RIE is performed for 25 seconds by using CF₄ gas (flow rate: 100 sccm) under the conditions of an in-chamber pressure of 5 mtorr (665 mPa), an RF source power of 330 W and an RF bias peak voltage of 100 V.

As shown in FIG. 1G, the polysilicon film 22 as an etching target film is etched by RIE by using HBr/O₂ or the like as etching gas. The upper hard mask 25 of polysilicon is also etched. Since the thickness of the upper hard mask of polysilicon is set equal to the thickness of the etching target film of polysilicon, the upper hard mask is extinguished before completion of etching the etching target film. The whole thickness of the lower hard mask 24 is maintained until the upper hard mask 25 is completely etched.

For example, as a first main etching (GME1) for gate electrodes, the main region of the etching target layer is etched by RIE for 25 seconds by using mixture gas of Cl₂/HBr/CF₄ (flow rate: 15/120/15 sccm) under the conditions of an in-chamber pressure of 8 mtorr (1064 mPa), an RF source power of 550 W and an RF bias peak voltage of 125 V. In the state that a portion of the etching target layer is left, the etching is switched to a second main etching (GME2) having a higher etching selectivity to gate oxynitride. For example, etching is performed for 20 seconds by using mixture gas of HBr/O₂ (flow rate: 180/5 sccm) under the conditions of an in-chamber pressure of 8 mtorr (1064 mPa), an RF source power of 385 W and an RF bias peak voltage of 65 V. After the etching end point is detected, over-etching (GOE) is performed at an etching selectivity raised further. For example, over-etching is performed for 40 seconds by using mixture gas of HBr/O₂/He (flow rate: 150/5/150 sccm) under the conditions of an in-chamber pressure of 80 mtorr (10640 mPa), an RF source power of 385 W and an RF bias peak voltage of 145 V.

As shown in FIG. 1H, the upper hard mask 25 of polysilicon is extinguished before the whole thickness of the polysilicon film 22 as the etching target film is etched.

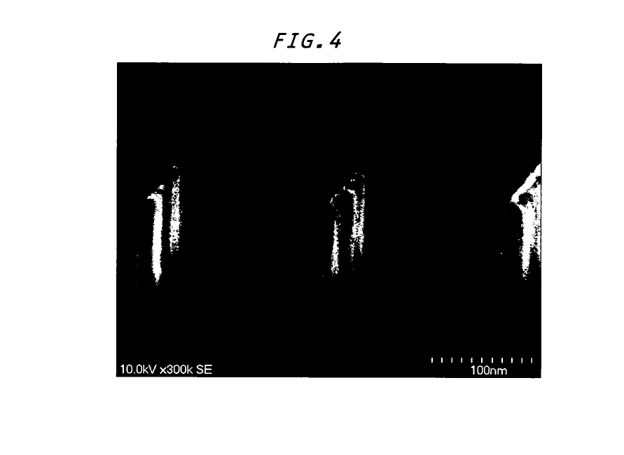

FIG. 4 is a SEM photograph showing polysilicon gate electrodes formed by the first embodiment method. It can be seen that polysilicon patterns having a width of about 15 to 20 nm are formed without pattern falling and breaking.

The characteristic feature of the first embodiment resides in that the upper hard mask film is made of polysilicon, the lower hard mask film is an inorganic insulating film conventionally used as a hard mask film, and after the upper hard mask film is patterned by using the resist pattern, the resist pattern is removed to realize the state that the resist pattern does not exist when the upper hard mask film is trimmed to a target pattern width. The feature of the first embodiment also resides in that the etching target film of polysilicon is etched by using as an etching mask the lamination of the upper and lower hard mask patterns to remove the upper hard mask pattern at the same time while the etching target film is patterned.

If a wafer is exposed in the atmospheric air after the upper hard mask is etched and before the resist pattern is removed, side wall deposition is oxidized or absorbs moisture in the atmospheric air. There is a possibility that pattern falling or the like occurs due to stress applied to the fine resist pattern. It is therefore preferable to maintain a vacuum atmosphere during the period from the upper hard mask etching to the ashing. For example, the processes shown in FIGS. 1B to 1D are executed in the same chamber. If a multi-chamber etcher is used, although it is not necessary to use the same chamber, it is preferable to move a wafer between chambers via a transport path in the vacuum atmosphere.

Stripping the resist pattern and trimming the upper hard mask are preferably performed under the chemistry of mixture of O₂ gas and gas which contains F such as CF₄. When the upper hard mask made of silicon material is etched, Si-containing by-products are deposited on the side walls. Residues cannot be removed completely only by O₂ gas ashing, resulting in a possible increase in line edge roughness. It is preferable to remove residues by using gas which can generate radicals of F-containing molecules. But, this is not necessary for wet process using HF or the like.

By selecting a mixture ratio of O₂ gas to F-containing gas such as CF₄, the lower hard mask can be etched at the same time while the upper hard mask is trimmed. It is possible in some cases to realize etching which is more inexpensive and has better controllability.

Stripping the resist pattern and trimming the upper hard mask can be performed basically by the same process series. These processes can be performed under the chemistry of mixture of O₂ gas and gas which contains F such as CF₄. With a proper amount of F, it is possible to realize a fast resist etching rate (ashing rate), the state without residues after resist removal, and a trimming rate (e.g., about 10 nm/min) capable of controlling the upper hard mask. If the amount of F is too large, the silicon etching rate rises excessively. At too high a etching rate, Si may be damaged during ashing and the shape and trimming controllability may be degraded. It is preferable to set F-containing gas flow less than O₂.

If silicon is etched in a large oxygen flow state, i.e., in a strong oxidizing state, the surface of silicon is oxidized and the surface of silicon oxide is etched with F-containing gas. In this case, the apparent etching rates of silicon and silicon oxide are close to each other. It becomes easy to obtain a low etching rate suitable for hard mask trimming.

During trimming the upper hard mask, the selectivity to the lower hard mask is not fundamentally an essential parameter. While the upper hard mask is trimmed, the lower hard mask may be etched. By trimming the upper hard mask and etching the lower hard mask at generally the same etch rate, the hard mask having vertical side walls can be formed.

It is preferable to etch and remove the upper hard mask film at the same time while the etching target film is etched, or to remove the upper hard mask film after the etching target film is etched. In the first embodiment, the etching target film and the upper hard mask film are made of polysilicon having the same initial thickness, and upper hard mask thickness is less than etching target polysilicon film just before gate poly etch (shown in FIG. 1F); Therefore, the upper hard mask film is basically removed while the etching target film is etched. If the upper hard mask film is left even after the etching target film is etched because the upper hard mask is thicker or has different etching characteristics, it is preferable to remove the upper hard mask film after the etching target film is processed. If the upper hard mask of silicon is conductive, it may cause electric short. Also in this case, if the upper hard mask is removed, this adverse influence can be eliminated. If only the lower hard mask of an inorganic insulating film is left, compatibility with a conventional hard mask process can be enhanced.

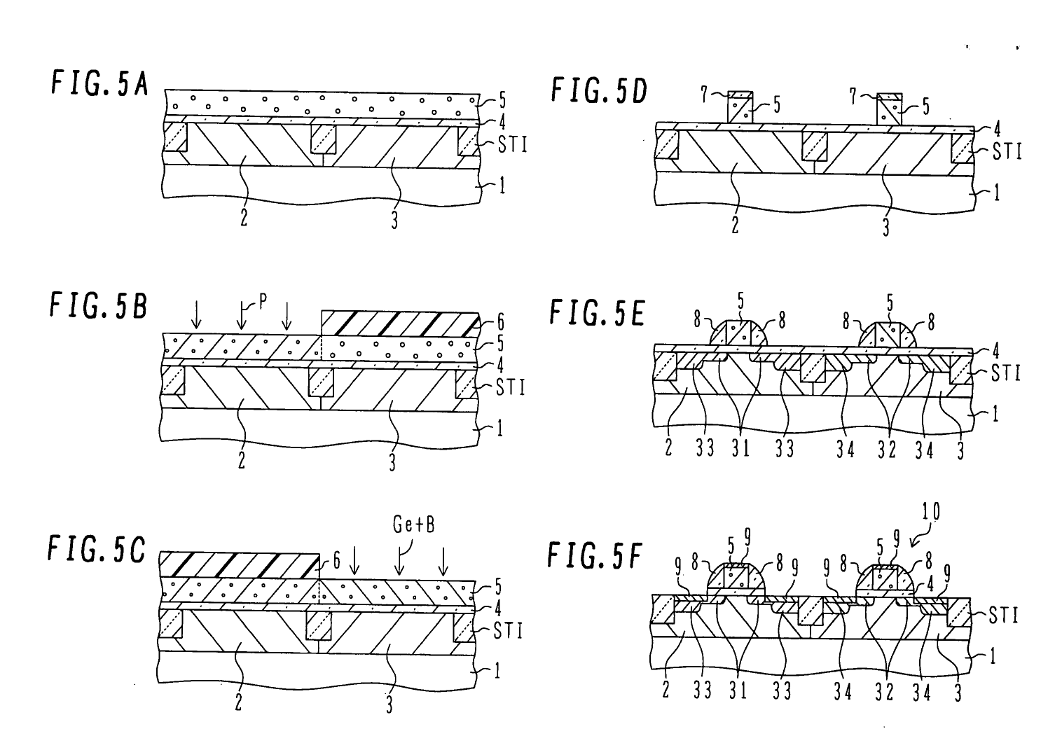

With reference to FIGS. 5A to 5F, a manufacture method for a CMOS semiconductor device will be described.

As shown in FIG. 5A, element isolation regions are formed in a silicon substrate 1 by shallow trench isolation (STI), p- and n-type impurity ions are implanted via openings formed through resist masks to form an n-channel MOS transistor p-type well 2 and a p-channel MOS transistor n-type well 3. A gate insulating film 4 of silicon oxynitride and a polysilicon film 5 are deposited on and above the silicon surface. The gate insulating film 4 and polysilicon film 5 correspond to the gate insulating film 21 and gate electrode layer 22 shown in FIG. 1A, respectively.

As shown in FIG. 5B, the p-MOS region 3 is covered with a resist mask 6, and n-type impurity ions of phosphorus P are implanted into the polysilicon film 5 above the n-MOS region at an acceleration energy of 10 keV and a dose of 1×10¹⁵/cm² (hereinafter denoted as 1E15, and etc).

As shown in FIG. 5C, the n-MOS region 2 is covered with a resist mask 6, and neutral impurities Ge are implanted into the polysilicon film 5 above the p-MOS region at an acceleration energy of 20 keV and a dose of 1E15 to pre-amorphousize the polysilicon film 5. The amorphousized silicon film is effective for preventing B from being pierced. After pre-amorphousizing, p-type impurity ions B are implanted at an acceleration energy of 5 keV and a dose of 1E15. The amorphous silicon film is thereafter transformed into a polysilicon film. At this time, implanted impurity ions may be activated.

A lower hard mask film of silicon oxide and an upper hard mask film of polysilicon are formed on and above the polysilicon film 5, and the processes shown in FIGS. 1A to 1H are executed to form gate electrodes having a desired gate length.

FIG. 5D shows the state that the gate electrodes are formed. The silicon oxide film 7 used as the lower hard mask is left on the polysilicon film 5.

As shown in FIG. 5E, by using the gate electrode and a resist pattern as a mask, n-type impurity ions As are implanted into the n-MOS region to form n-type extensions 31. Similarly, by using the gate electrode and a resist pattern as a mask, p-type impurity ions B are implanted into the p-MOS region to form p-type extensions 32. Pockets may be formed by implanting impurity ions of the opposite conductivity types.

A silicon oxide film is deposited to a thickness of 100 nm by thermal CVD, for example, at 580° C., and etched by RIE to leave side wall spacers 8 only on the side walls of the gate electrodes. The silicon oxide films 7 used as the lower hard mask are also etched and removed. Then, n-type impurity ions P are implanted into the n-MOS region and p-type impurity ions B are implanted into the p-MOS region, and the implanted ions are activated to form low resistance source/drain regions 33 and 34.

As shown in FIG. 5F, for example, a cobalt film is deposited by sputtering, and a salicide process is executed to form silicide layers 9. With these processes, a CMOS semiconductor device 10 is completed.

In the first embodiment, stacked on the gate insulating film of silicon oxynitride are the gate electrode layer of silicon as the etching target layer, the silicon oxide film as the lower hard mask, and the polysilicon film as the upper hard mask. The materials of the gate insulating film, gate electrode, lower hard mask film and upper hard mask film are not limited to those described above. The etching target layer may not be a gate electrode but a wiring.

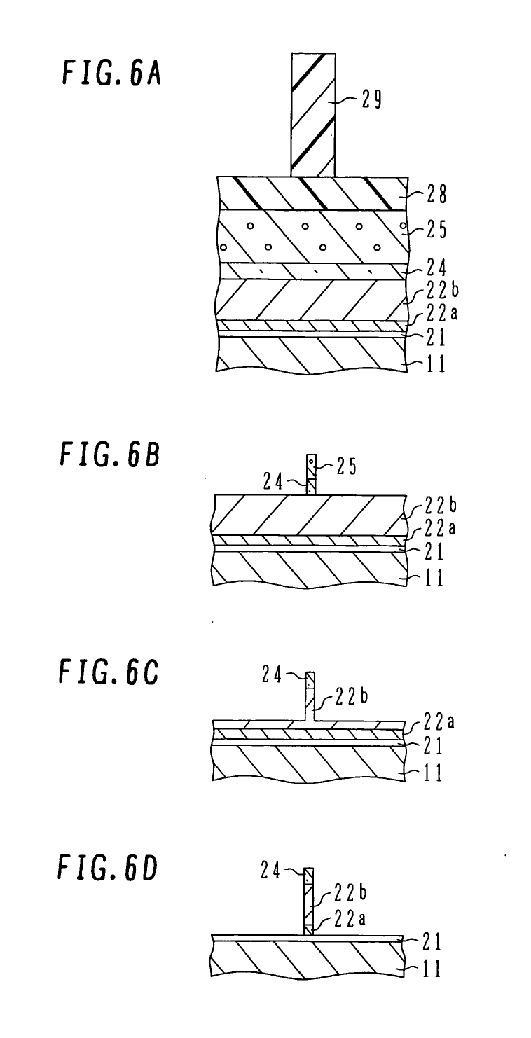

FIGS. 6A to 6D are cross sectional views of a semiconductor substrate illustrating main processes of a micro structure manufacture method according to the second embodiment.

As shown in FIG. 6A, a gate insulating film 21 of HfSiON having a thickness of 5 nm is formed on the surface of a silicon substrate. A TiN layer 22a having a thickness of 10 nm and a W layer 22b having a thickness of 70 nm are stacked on the gate insulating film by CVD or sputtering (PVD) to form a gate electrode layer.

For example, the HfSiON film 21 is formed by thermally oxidizing the surface of the silicon substrate and growing an HfON film on silicon oxide by CVD. Nitrogen may be introduced after thermal oxidation. The HfSiON film may be grown by CVD. By using material having a dielectric constant higher than that of silicon oxide, the physical thickness of the gate insulating film can be made thick while a silicon oxide equivalent thickness is maintained low, and leakage current can be suppressed. The material having a dielectric constant higher than that of silicon oxide may be ZrO₂, HfO₂, Al₂O₃, AlHfSiON, Ta₂O₅, and these materials doped with N or Si.

The W layer 22b constitutes a main region of the gate electrode. The material of this layer may be other refractory metals such as Ta and Mo, and other metals such as Zr, Al, Ti and Ni. The TiN layer 21 a determines a work function of the gate electrode. Depending upon a target work function, other materials may be used such as TaN, TaSiN, WN and Ru.

An SiN film 24 as a lower hard mask film having a thickness of 50 nm and a polysilicon film 25 as an upper hard mask film having a thickness of 105 nm are formed on and above the gate electrode layer by thermal CVD or the like. The materials of the gate insulating film, gate electrode layer and lower hard mask film are different from those of the first embodiment. A BARC film 28 and a resist film 29 are formed by the processes similar to those of the first embodiment. The processes from a resist pattern forming process to an upper hard mask etching and trimming process are similar to those of the first embodiment.

FIG. 6B illustrates a process of etching the lower hard mask film 24 of SiN. The SiN lower hard mask film 24 is etched by RIE using CF₄ or the like as etching gas. A hard mask for etching an etching target film is constituted of a lamination of the upper hard mask 25 of polysilicon and the lower hard mask 24 of SiN.

As shown in FIG. 6C, the W layer 22b is etched by RIE using mixture gas of SF₆/N₂ or the like. This etching extinguishes the upper hard mask 25 of polysilicon. NF₃ gas may be used in place of SF₆ gas.

As shown in FIG. 6D, the TiN layer 22a is etched by using mixture gas of, for example, Cl₂/BCl₃/CHF₃. The gate insulating film 21 of HfSiON can be used as an etch stopper. Even if the upper hard mask of polysilicon is left, it may be removed by using mixture gas of HBr/O₂ or the like in the state that the gate insulating film is exposed.

In the second embodiment, the upper hard mask film is made of Si and the main region of the gate electrode is made of W. A W film may be used as the upper hard mask film. In this case, the upper hard mask film and the etching target film are made of the same material and can be etched at the same time independently from the etching conditions. In the first and second embodiments, the gate insulating film is used as the etch stopper when the gate electrode is etched. Another film may be used as the etch stopper.

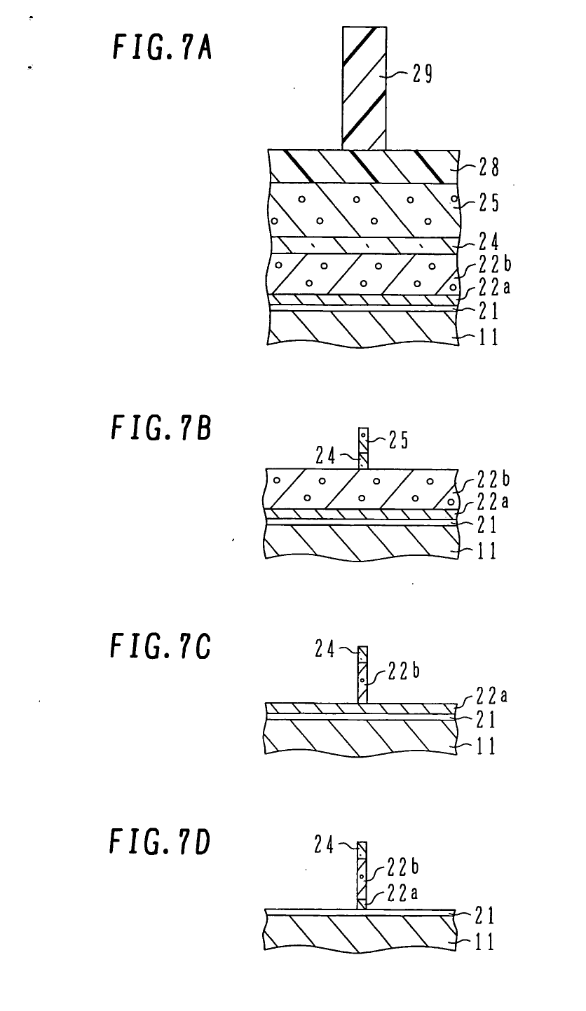

FIGS. 7A to 7D are cross sectional views of a semiconductor substrate illustrating the main processes of a micro structure manufacture method according to the third embodiment.

As shown in FIG. 7A, a polysilicon film 22b having a thickness of 100 nm is formed on a TaN layer 22a having a thickness of 5 nm to form a gate electrode layer. The TaN layer is deposited by sputtering (reactive sputtering). Other lamination structures are similar to those of the first embodiment.

FIG. 7B shows the state that a hard mask is formed, corresponding to FIG. 1F. The silicon surface of the upper gate electrode layer 22b is exposed.

FIG. 7C shows the state that the polysilicon gate electrode 22b is etched by using mixture gas of HBr/O₂ similar to the process shown in FIG. 1G. The TaN lower gate electrode 22a functions as an etch stopper. Even if the upper hard mask of polysilicon is left, it can be removed at this stage by over-etching.

FIG. 7D shows the state that the lower gate electrode layer 22a is etched by using BCl₃ gas or the like.

The present invention has been described in connection with the preferred embodiments. The invention is not limited only to the above embodiments. For example, in the above embodiments, a wiring is formed by replacing the gate electrode layer with a wiring layer and the gate insulating film with an interlayer insulating film. Although the etching target film of silicon is etched by using HBr-containing gas, it may be etched by using gas which contains one or more of Cl₂, HBr, Br₂, Hl, HCl and BCl₃. It will be apparent to those skilled in the art that other various modifications, improvements, combinations, and the like can be made.

What are claimed are:

1. A micro structure manufacture method comprising the steps of:
(a) preparing an etching object having an etching target film, provided with a lower hard mask layer and an upper hard mask layer stacked on the etching target film;
(b) forming a resist pattern above said etching object;
(c) etching said upper hard mask film by using said resist pattern as an etching mask to form an upper hard mask;
(d) after said step (c), removing said resist pattern;
(e) after said step (d), thinning said upper hard mask by etching;
(f) etching said lower hard mask film by using said thinned upper hard mask as an etching mask to form a lower hard mask; and
(g) etching said etching target film by using said upper hard mask and said lower hard mask as an etching mask,
wherein said upper hard mask film is capable of being more easily etched, using said resist pattern as a mask, than said lower hard mask film.

2. The micro structure manufacture method according to claim 1, wherein said step (g) removes said upper hard mask at the same time.

3. The micro structure manufacture method according to claim 1, wherein said etching object has an etch stop film under said etching target film, said step (g) etches said etching target film by using said etch stopper film as a stopper, and the micro structure manufacture method further comprises the step of:
(h) after said step (g), removing said upper hard mask being left by etching.

4. The micro structure manufacture method according to claim 1, wherein said resist pattern in said step (b) has a minimum line width of 150 nm or narrower.

5. The micro structure manufacture method according to claim 4, wherein said upper hard mask thinned in said step (e) has a minimum line width of 100 nm or thinner.

6. The micro structure manufacture method according to claim 1, wherein the micro structure is a micro structure of a semiconductor device, and said etching target film constitutes a gate electrode or a wiring.

7. The micro structure manufacture method according to claim 6, wherein said etching target film and said upper hard mask film includes a silicon film or a refractory metal film, and said lower hard mask film is made of inorganic insulator.

8. The micro structure manufacture method according to claim 1, wherein at least one of said steps (d) and (e) is executed by using etching gas which is a mixture of O₂-containing gas and fluorine-containing gas of at least one of CF₄, CHₓF_{y}, CₓF_{y}, SF₆ and NF₃.

9. The micro structure manufacture method according to claim 8, wherein a ratio of the O₂-containing gas to fluorine-containing gas in the etching gas is larger than 1.

10. The micro structure manufacture method according to claim 7, wherein etching in said step (g) is performed by using etching gas which contains one or more of Cl₂, HBr, Br₂, Hl, HCl and BCl₃.

11. The micro structure manufacture method according to claim 1, wherein said step (e) etches said lower hard mask film at the same time.

12. The micro structure manufacture method according to claim 1, wherein said resist pattern is an ArF resist film.

13. The micro structure manufacture method according to claim 12, wherein the micro structure is a micro structure of a semiconductor device, and said etching target film is a gate electrode film formed on a gate insulating film formed on a semiconductor substrate surface.

14. The micro structure manufacture method according to claim 13, wherein said etching target film and said upper hard mask film are polysilicon films, and said lower hard mask film is a silicon oxide film or a silicon nitride film.

15. The micro structure manufacture method according to claim 14, wherein a thickness of said upper hard mask film is equal to or thinner than a thickness of said etching target film, and said step (g) removes said upper hard mask.

16. The micro structure manufacture method according to claim 15, wherein said step (g) patterns a gate electrode, and the micro structure manufacture method further comprises:
(i) after said step (g), depositing a silicon oxide film or a silicon nitride film covering said gate electrode, and reactive-etching said silicon oxide film or said silicon nitride film to form side wall spacers on side walls of said gate electrode, while removing said lower hard mask at the same time.

17. The micro structure manufacture method according to claim 13, wherein said etching target film includes a TiN film and a W film formed on said TiN film.

18. The micro structure manufacture method according to claim 17, wherein said step (g) includes the step of:
(g-1) etching said W film by using said TiN film as an etch stopper.

19. The micro structure manufacture method according to claim 13, wherein said etching target film includes a TaN film and a silicon film formed on said TaN film, and said upper hard mask film is a silicon film.

20. The micro structure manufacture method according to claim 19, wherein said step (g) includes the step of:
(g-1) etching said silicon film by using said TaN film as an etch stopper.
